(19) United States
(12) Patent Application Publication
(10) Pub. No.: US 2025/0120052 A1
(43) Pub. Date: Apr. 10, 2025

(54) COOLING DISTRIBUTION UNITS AND IN-RACK THERMAL MANAGEMENT SYSTEMS

(71) Applicant: Nvidia Corporation, Santa Clara, CA (US)

(72) Inventors: Ryan Albright, Beaverton, OR (US); Tahir Cader, Spokane Valley, WA (US); Aaron Carkin, Hillsboro, OR (US); Siddha Ganju, San Jose, CA (US); Kenneth Misin, Campbell, CA (US); William Mecham, Elk Grove, CA (US); William Ryan Weese, Portland, OR (US); Benjamin Goska, Portland, OR (US); Jordan Levy, Portland, OR (US); Michael Thompson, Wilsonville, OR (US); Elad Mentovich, Tel Aviv (IL); Fred Devoir, Pilot Point, TX (US)

(21) Appl. No.: 18/377,017

(22) Filed: Oct. 5, 2023

(51) Int. Cl. H05K 7/20

(52) U.S. Cl. CPC H05K 7/20836

(57) ABSTRACT

Devices, apparatuses, and systems for thermal management in networking and computing systems are provided. An example in-rack thermal management system includes a cooling distribution unit (CDU) that includes a housing that defines a fluid inlet and a fluid outlet, thermal management components supported by the housing, and direct mechanical connections coupled with the fluid inlet and the fluid outlet. The in-rack thermal management system includes a fluid distribution system that includes a primary fluid channel directly coupled with the direct mechanical connection of the fluid inlet, and a secondary fluid channel directly coupled with the direct mechanical connection of the fluid outlet. In operation, the thermal management components dissipate heat of a fluid received by the CDU via the fluid inlet. The direct mechanical connections directly interface with the fluid distribution system to provide fluid communication between the CDU and the fluid distribution system to maximize dimensions of the housing.

### TECHNOLOGICAL FIELD

Example embodiments of the present disclosure relate generally to high-performance networking and computing systems and, more particularly, to thermal management solutions for dissipating heat generated in these systems.

### BACKGROUND

High-performance computing systems, such as those used in datacenter implementations and other networking environments (e.g., datacom, telecom, and/or other similar data/communication transmission networks), may leverage numerous computing components (e.g., central processing units (CPUs), graphics processing unit (GPUs), data processing units (DPUs), etc.) to perform the operations associated with these environments. During operation, the heat generated by these components may impact the overall operation of the computing systems. Applicant has identified a number of deficiencies and problems associated with conventional thermal management solutions associated with computing systems. Through applied effort, ingenuity, and innovation, many of these identified problems have been solved by developing solutions that are included in embodiments of the present disclosure, many examples of which are described in detail herein.

### BRIEF SUMMARY

Devices, apparatuses, systems, and methods are provided for cooling distribution units and associated in-rack thermal management systems. An example in-rack thermal management system may include a cooling distribution unit (CDU) and a fluid distribution system. The CDU may include a housing defining a fluid inlet and a fluid outlet. The CDU may further include one or more thermal management components supported by the housing, and one or more direct mechanical connections coupled with the fluid inlet and the fluid outlet. The fluid distribution system may include a primary fluid channel directly coupled with the direct mechanical connection of the fluid inlet, and a secondary fluid channel directly coupled with the direct mechanical connection of the fluid outlet. In operation, the one or more thermal management components may be configured dissipate heat of a fluid received by the CDU via the fluid inlet. The direct mechanical connections may be configured to directly interface with the fluid distribution system to provide fluid communication between the CDU and the fluid distribution system so as to maximize one or more dimensions of the housing.

In some embodiments, the direct mechanical connections may be configured to directly interface with the fluid distribution system in the absence of external fluid conduits.

In some embodiments, the direct mechanical connections may be configured to be removably attached with the fluid distribution system without external fluid conduits extending therebetween.

In some embodiments, the one or more direct mechanical connections may include one or more blind mate connectors.

In some embodiments, a first temperature associated with the fluid received by the fluid inlet may be greater than a second temperature associated with the fluid exiting the housing via the fluid outlet.

In some embodiments, the housing further defines one or more support rails by which the housing may be positioned within a datacenter rack.

In some further embodiments, the housing, via movement along the one or more support rails, may be configured to be removably attached with the fluid distribution system.

In some embodiments, the one or more dimensions of the housing may define an internal dimension such that the housing is further configured to support one or more redundant thermal management components.

In some embodiments, the one or more dimensions of the housing may define an internal dimension such that at least one of the thermal management components supported by the housing includes an increased capacity.

The in-rack thermal management system may further include a server housing defining a server inlet and a server outlet, one or more processing components supported by the server housing, and one or more direct mechanical connections coupled with the server inlet and the server outlet. In such an embodiment, the one or more direct mechanical connections may be configured to directly interface with the fluid distribution system to provide fluid communication between the server housing and the fluid distribution system.

In some further embodiments, the direct mechanical connections of the server housing may be configured to directly interface with the fluid distribution system in the absence of external fluid conduits.

The above summary is provided merely for purposes of summarizing some example embodiments to provide a basic understanding of some aspects of the present disclosure. Accordingly, it will be appreciated that the above-described embodiments are merely examples and should not be construed to narrow the scope or spirit of the disclosure in any way. It will be appreciated that the scope of the present disclosure encompasses many potential embodiments in addition to those here summarized, some of which will be further described below.

### BRIEF DESCRIPTION OF THE DRAWINGS

Having described certain example embodiments of the present disclosure in general terms above, reference will now be made to the accompanying drawings. The components illustrated in the figures may or may not be present in certain embodiments described herein. Some embodiments may include fewer (or more) components than those shown in the figures.

FIG. 1 illustrates an example datacenter including racks for implementing one or more embodiments described herein;

FIG. 2 illustrates an example datacenter rack of the example datacenter of FIG. 1 supporting server components in accordance with some embodiments described herein;

FIG. 3 illustrates the example server of FIG. 2 including example graphics processing units (GPUs) as example processing components in accordance with some embodiments described herein;

FIG. 4 illustrates an example in-rack thermal management system in accordance with some embodiments described herein;

FIG. 5 illustrates an example cooling distribution unit (CDU) of the in-rack thermal management system in accordance with some embodiments described herein;

FIG. 6 illustrates an example blind mate connector for fluidically coupling the CDU with a fluid distribution system of the in-rack thermal management system of FIG. 4 in accordance with some embodiments described herein;

FIG. 7 illustrates installation of an example CDU within an example datacenter rack in accordance with some embodiments described herein;

FIG. 8 illustrates the installation of FIG. 7 including support rails for removably attaching the CDU with the datacenter rack in accordance with some embodiments described herein;

FIG. 9 illustrates one or more thermal management components of an example CDU in accordance with some embodiments described herein; and

FIG. 10 illustrates increased dimensions provided by the example CDUs of the present disclosure in accordance with some embodiments described herein.

### DETAILED DESCRIPTION

### Overview

Embodiments of the present disclosure now will be described more fully hereinafter with reference to the accompanying drawings in which some but not all embodiments are shown. Indeed, the present disclosure may be embodied in many different forms and should not be construed as limited to the embodiments set forth herein; rather, these embodiments are provided so that this disclosure will satisfy applicable legal requirements. Like numbers refer to like elements throughout. As used herein, terms such as “front,” “rear,” “top,” etc. are used for explanatory purposes in the examples provided below to describe the relative position of certain components or portions of components. Furthermore, as would be evident to one of ordinary skill in the art in light of the present disclosure, the terms “substantially” and “approximately” indicate that the referenced element or associated description is accurate to within applicable engineering tolerances.

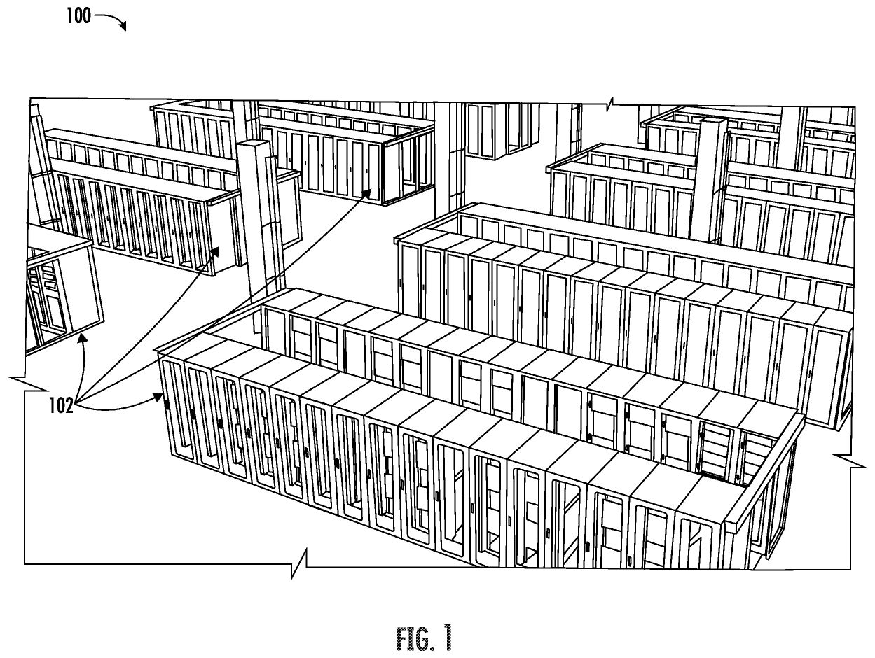

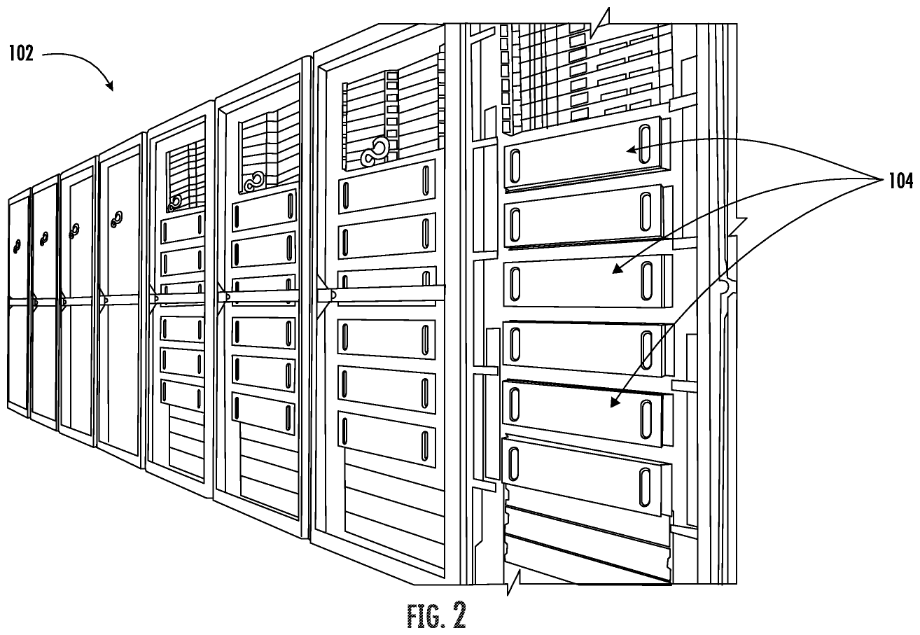

As described above, datacenters and other networking environments (e.g., datacom, telecom, and/or other similar data/communication transmission networks), may leverage numerous electronic or computing components (e.g., CPUs, GPUs, DPUs, etc.) to perform the operations associated with these environments. For example, as shown in FIGS. 1-2, a datacenter 100 may include various datacenter racks 102 that support servers 104 configured to perform operations (e.g., high performance computing operations, artificial intelligence operations, machine learning modeling, virtual reality (VR) generation, and/or the like) associated with the datacenter 100. The racks 102 may, in some instances, include a plurality of servers 104 that are each inserted into the enclosure defined by the datacenter rack 102. These datacenters 100 may include any number of racks 102 (e.g., cabinets, housings, enclosures, etc.) at various positions (e.g., rows, columns, etc.) based on the intended application of the datacenter 100 and/or the constraints associated with the physical location that houses the datacenter 100.

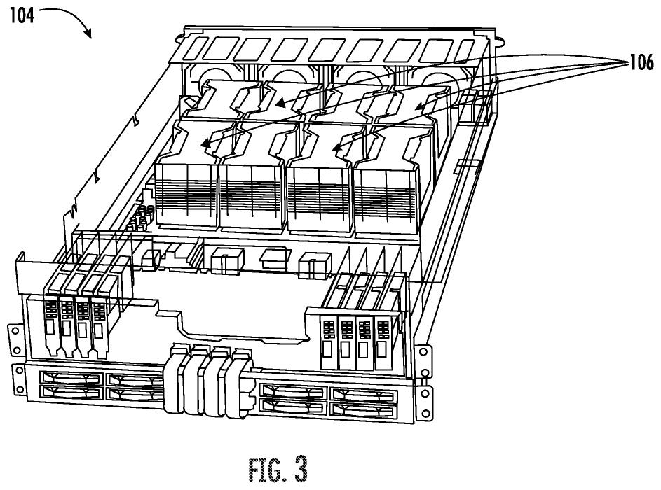

With reference to FIG. 3, the servers 104 of the datacenter 100 may employ various processing components 106 (e.g., computing components or the like) configured to perform the various operations of the datacenter 100. By way of example, the example server 104 of FIG. 3 is illustrated with a plurality of GPUs that may operate as the processing components 106. The server 104 may include any number of primary processing components (e.g., CPUs, GPUs, DPUs, etc.) as well as related secondary components (e.g., communication interfaces, memory devices, etc.) that support the operations of these primary computing components. During performance of the operations associated with the datacenter 100, the one or more processing components 106 may generate heat that may impact the overall operation or performance of the server 104. The thermal burden of some of these components may be further increased in high performance/power computing systems, such as high-power GPU systems, with rapidly increasing power consumption levels. To attempt to dissipate the heat or otherwise reduce the thermal burden of the server 104 and processing components 106, the datacenter rack 102 may employ thermal management solutions (e.g., air or liquid cooling devices).

By way of example, and as described further hereinafter with reference to the cooling distribution units (CDUs) of the present disclosure, datacenter thermal management solutions may leverage devices that circulate fluid (e.g., water of the like) having a temperature that is less than the temperature of the processing components 106 in order to lower the relative temperature of these processing components 106. In some instances, the rack 102 may support a CDU that houses, in whole or in part, thermal management components (e.g., heat exchangers, pumps, etc.) that are in fluid communication with the one or more processing components 106 of the server(s) 104. These conventional systems, however, often rely upon external fluid conduits (e.g., channels, piping, hoses, etc.) to connect (e.g., provide fluid communication between) the CDU and the server(s) 104. For example, a conventional CDU implementation may leverage a pair of hoses that connect the CDU (e.g., inlet and exhaust) with a fluid distribution system (e.g., collection of fluid channels).

As would be evident to one of ordinary skill in the art in light of the present disclosure, the dimensions (e.g., size and shape) of the rack 102 housing the server 104 and the example CDU limit the volume of usable space within rack 102. As such, the hoses (e.g., fluid conduits or the like) used by conventional systems limit the associated size of the CDU or otherwise occupy valuable space within the datacenter rack 102. Additionally, in order to maintain fluid communication during movement of the CDU within the datacenter rack 102 (e.g., translation of the CDU for maintenance or the like), the size (e.g., length) of the associated hoses used by conventional CDUs must be increased further increasing the space occupied by these hoses. Still further, conventional hose-based thermal management implementations (e.g., fluid conduits or the like) may have limited heat dissipation capabilities due to the maximum flow limits (e.g., of cooling fluid) associated with these hoses (e.g., limited by hose bend radius or the like).

In order to address these issues and others, the embodiments of the present disclosure may leverage direct mechanical connections for establishing fluid communication between CDUs and associated in-rack fluid distribution systems, thereby resulting in a maximization of the dimensions of the CDU. For example, the embodiments described herein may allow for the CDU to directly interface with the fluid distribution system in the absence of external fluid conduits, such as via one or more blind mate connectors. By establishing this direct connection, the CDUs of the present disclosure may (1) increase in size (e.g., volume) resulting in an increase in the capacity of the thermal management components therein, (2) increase in size (e.g., volume) and thereby increase the number of thermal management components therein; and/or (3) enable an increase in the number of components (e.g., CDUs, servers, etc.) housed by the datacenter rack. Furthermore, the direct mechanical connections of the present disclosure (e.g., blind mate connectors or the like) improve the serviceability of the CDU relative to conventional solutions.

### Example CDUs and In-Rack Thermal Management Systems

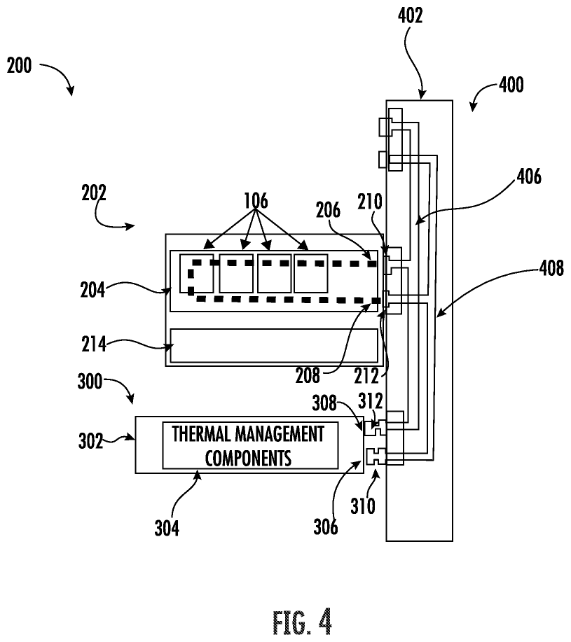

With reference to FIG. 4, an example in-rack thermal management system 200 (e.g. system 200) of the present disclosure is illustrated. As shown, the system 200 may include a server 202, a CDU 300, and a fluid distribution system 400. The server 202 may include a housing 204 that supports one or more processing components 106. As described above, the processing components 106 (e.g., computing components or the like) may refer to the components of the datacenter rack 102 that are configured to perform the various operations of the datacenter 100. By way of continued example, the example server 202 of FIG. 4 may include a plurality of GPUs that may operate as the processing components 106. Although described hereinafter with reference to GPUs as the example processing components 106, the present disclosure contemplates that the server 202 may include processing components 106 of any number, type, configuration, etc. (e.g., CPUs, DPUs, GPUs, memory devices, communication interfaces, etc.) based upon the intended application of the server 202. Said differently, the thermal management systems and techniques described herein may be configured to dissipate heat generated by any component of the server 202. Additionally, the present disclosure contemplates that the server 202 may include any number of associated substrates, printed circuit boards (PCBs), etc. configured to at least partially provide physical support to and electrical connectivity between (e.g., via wires, electrical traces, etc.) the processing components 106 described herein.

The housing 204 of the server 202 may define any structure, enclosure, etc. configured to support the processing components 106 described above. As such, the dimensions (e.g., size and shape) of the housing 204 may vary based upon the number and/or type of processing components 106 supported therein, the associated dimensions of the datacenter rack 102 within which the server 202 may be positioned, and/or the like. As described hereinafter, one or more dimensions of the server housing 204 may be maximized by the use of direct mechanical connections 210, 212 with the fluid distribution system 400. In some embodiments, the server 202 may further include other processing components 214, the temperature of which may be managed by different thermal management components. By way of a non-limiting example, the server 202 may include a first portion of the server housing 204 that is associated with the processing components 106 (e.g., the GPUs) that are liquid cooled and a second portion that is associated with processing components 214 (e.g., CPUs) that are air cooled. The present disclosure contemplates that, in some embodiments, different processing components of the server 202 may be cooled by different mechanisms or techniques based upon the different thermal burdens experienced by these components.

The server housing 204 may also define a server inlet 206 and a server outlet 208 that may be used to establish fluid communication between the server housing 204 and the fluid distribution system 400. The server inlet 206 and the server outlet 208 may refer to any opening, aperture, hole, etc. by which the server 202 may receive fluid from or direct fluid to, respectively, the fluid distribution system 400. For example, the server 202 may include a fluid loop (e.g., internal fluid conduit(s) or the like) that fluidically couples the server inlet 206 and the server outlet 208. In operation, fluid may be received by the server housing 204 from the fluid distribution system 400 at the server inlet 206, and the fluid loop may direct the fluid from the server inlet 206 into thermal contact with the processing components 106. The fluid loop may then direct the fluid from the processing components 106 to the server outlet 208 and into the fluid distribution system 400. As would be evident to one of ordinary skill in the art in light of the present disclosure, in order to dissipate the heat generated by the processing components 106, a temperature of the fluid received by the server inlet 206 may be less than a temperature of the fluid exiting the server housing 204 via the server outlet 208.

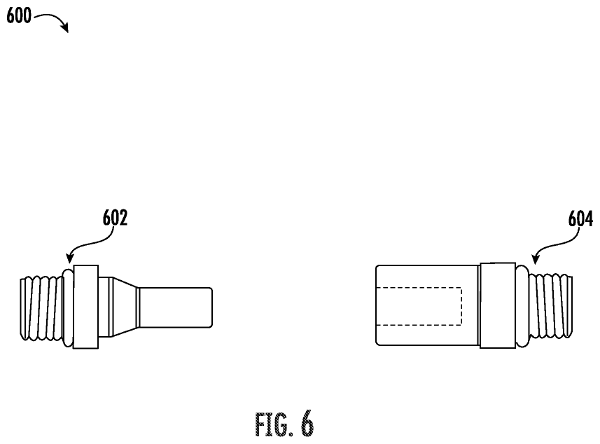

As described more fully hereinafter with reference to the CDU 300, the server 202 may further include direct mechanical connections 210, 212 coupled with the server inlet 206 and the server outlet 208, respectively. The direct mechanical connections 210, 212 of the server housing 204 may be configured to directly interface with the fluid distribution system 400 in the absence of external fluid conduits. In other words, the one or more direct mechanical connections 210, 212 may be configured to directly interface with the fluid distribution system 400 to provide fluid communication between the server housing 204 and the fluid distribution system 400. For example, the direct mechanical connections 210, 212 may include one or more blind mate connectors as described hereafter with reference to FIG. 6. The use of the direct mechanical connections 210, 212 may, as described above, operate to increase one or more dimensions of the server housing 204 (e.g., by occupying the space of the datacenter rack conventionally occupied by hoses). In this way, for example, the operational capabilities of the server 202 may be increased, such as by including additional processing components 106 which historically were too large to fit within the dimensions of the server housing 204.

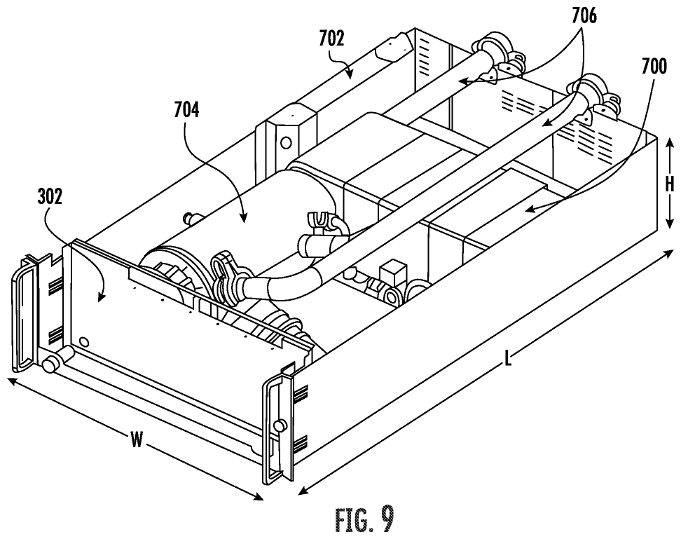

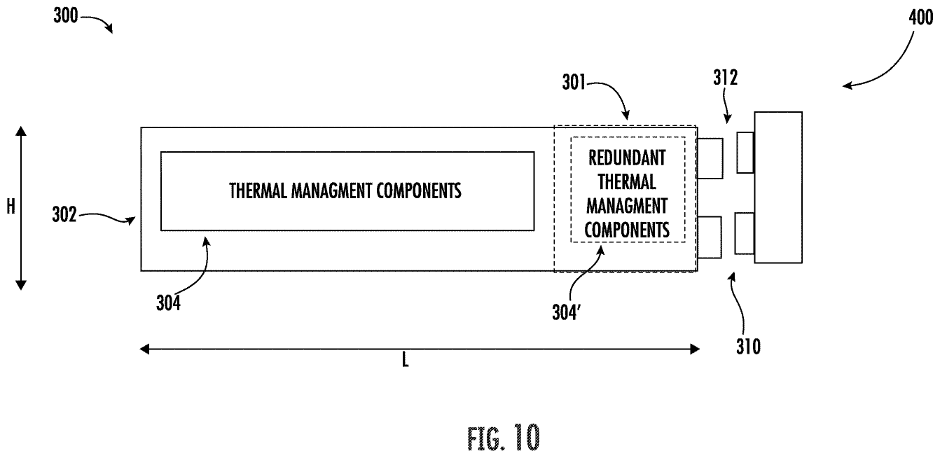

With continued reference to FIG. 4, the system 200 may include a CDU 300 that includes a housing 302. As shown, the CDU 300 may include one or more thermal management components 304 supported by the housing 302. The housing 302 may define a fluid inlet 306 and a fluid outlet 308 that may be used to establish fluid communication between the CDU housing 302 and the fluid distribution system 400. The fluid inlet 306 and the fluid outlet 308 may refer to any opening, aperture, hole, etc. by which the CDU 300 may receive fluid from or direct fluid to, respectively, the fluid distribution system 400. For example, the CDU 300 may include one or more internal fluid conduits, channels, etc. (e.g., thermal management components 304) that fluidically couple the fluid inlet 206 and the fluid outlet 208. As described above and further hereafter with reference to FIGS. 9-10, the thermal management components 304 of the CDU 300 may refer to components, devices, elements, etc. configured to dissipate heat of a fluid received by the CDU 300. By way of example, the CDU 300 may include various internal fluid conduits, channels, etc. for directing fluid within the CDU 300, one or more fill pumps, circuit pumps, etc. configured to cause movement of the fluid within the CDU 300 and/or the fluid distribution system 400, one or more temperature sensors configured to determine the temperature of the fluid within the CDU 300, a heat exchanger configured to dissipate heat associated with the fluid within the CDU 300, and/or the like. The present disclosure contemplates that the CDU 300 may include thermal management components 304 of any type, configuration, etc. based upon the intended application of the CDU 300, the thermal burden of the server(s) 202, and/or the like.

In operation, fluid may be received by the CDU housing 302 from the fluid distribution system 400 at the fluid inlet 306, and the internal conduits, channels, etc. of the CDU 300 (e.g., example thermal management components 304) may direct the fluid into thermal contact with an example heat exchanger (e.g., another thermal management component 304). The heat exchanger (e.g., plate heat exchanger or the like) may be configured to dissipate the heat of the fluid and further direct the fluid to the fluid outlet 308 and into the fluid distribution system 400. As would be evident to one of ordinary skill in the art in light of the present disclosure, a temperature of the fluid received by the fluid inlet 306 of the CDU 300 may be greater than a temperature of the fluid exiting the CDU 300 via the fluid outlet 308. In other words, the CDU 300 may operate to remove heat (e.g., reduce the temperature) of the fluid within the CDU 300 such that relatively lower temperature fluid may be recirculated to the server 202 for dissipating heat generated by the processing components 106. The heat that is dissipated from the cooling fluid by the heat exchanger may be further dissipated to an external environment of the system 200. Said differently, the datacenter 100 (e.g., the facility that houses the system 200) may employ further loops (e.g., fluid conduits or the like) that are thermally coupled with the CDU 300 so as to remove the heat dissipated by the CDU 300 from the system 200. The present disclosure contemplates that the example datacenters 100 employing the systems 200 described herein may leverage any mechanism, structure, technique, and/or the like for removing the heat from the CDU 300 to an external environment of the system 200.

Although described herein with reference to a cooling distribution unit (CDU), the present disclosure contemplates that the system 200 may include any thermal management unit based upon the intended application of the system 200. For example, in some instances, such a thermal management unit (e.g., having the structure and components of CDU 300) may be configured to heat the fluid received by the thermal management unit (e.g., a heating system as opposed to a cooling system). In such an embodiment, a first temperature associated with the fluid received by the fluid inlet of the CDU may be less than a second temperature associated with the fluid exiting the housing via the fluid outlet. Said differently, although the present disclosure refers to a cooling distribution unit (CDU) 300, the embodiments described herein may be equally applicable to heating implementations in which the CDU 300 operates to increase the temperature of the fluid within the system 200 so as to transfer heat to the one or more processing components 106 of the server 202.

The system 200 may further include a fluid distribution system 400 configured to provide fluid communication between the server 202 and the CDU 300. As shown in FIG. 3, the fluid distribution system 400 may refer to the collection of fluid channels that extend between the server 202 and the CDU 300 so as to direct fluid between the respective inlets and outlets of the server 202 and the CDU 300. For example, the fluid distribution system 400 may include a primary fluid channel 408 that is directly coupled with the fluid inlet 306 of the CDU 300 and the server outlet 208 of the server 202. The fluid distribution system 400 may include a secondary fluid channel 406 that is directly coupled with the fluid outlet 308 of the CDU 300 and the server inlet 206 of the server 202. In operation, fluid having a relatively lower temperature (e.g., lower than the operating temperature of the processing components 106) may be directed by the secondary fluid channel 406 from the CDU 300 to the server 202 and received by the server 202 via the server inlet 206. The relatively cooler fluid may dissipate the heat of the processing components 106 of the server 202 as described above and exit the server 202 via the server outlet 208 into the primary fluid channel 408. The relatively warmer fluid is directed by the primary fluid channel 408 to the CDU 300 and received by the CDU 300 via the fluid inlet 306. The thermal management components 304 of the CDU 300 may dissipate the heat of the fluid (e.g., via heat exchangers or the like) so as to reduce the temperature of the fluid that is exiting the CDU 300 via the fluid outlet 308. This relatively cooler fluid is recirculated to the server 202 by the fluid distribution system 400 for iterative or continuous cooling.

In some embodiments, as shown in FIG. 4, the fluid distribution system 400 may include a housing 402 that supports the primary fluid channel 408 and/or the secondary fluid channel 406. In such an embodiment, the housing 402 may at least partially enclose these channels 406, 408 and may be located separate from the datacenter rack 102 supporting the server(s) 202 and the CDU 300. By way of a non-limiting example, the housing 402 of the fluid distribution system 400 may, in some embodiments, be a modular component that is attached to, located proximate, and/or the like the datacenter rack 102. In other embodiments, the datacenter rack 102 described above may support, in whole or in part, the fluid channels 406, 408 such that a separate housing 402 is unnecessary. For example, each of the components of the system 200 may be supported by the datacenter rack 102 such that the system operates as an in-rack thermal management system.

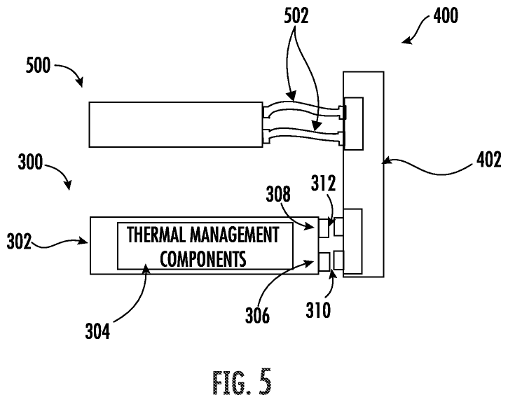

In order to maximize one or more dimensions of the housing 302 of the CDU 300 as described above, the CDU 300 may include one or more direct mechanical connections 310, 312 coupled with the fluid inlet 306 and the fluid outlet 308 as shown in FIGS. 5-6. With reference to FIG. 5, a CDU 500 is illustrated that is in fluid communication with the fluid distribution system 400 via one or more external conduits 502 (e.g., external hoses or the like). As shown, the hoses 502 may interface with the CDU 500 to connect CDU 500 with the fluid distribution system 400; however, these external conduits 502 occupy additional space that may otherwise be used by the CDU 500. As such, the CDU 300 of the present disclosure may leverage a direct mechanical connection 310 that is coupled with the fluid inlet 306 and a direct mechanical connection 312 that is coupled with the fluid outlet 308 so as to remove or otherwise reduce the volume within the datacenter rack 102 that is occupied for this connection. The direct mechanical connections 310, 312 may be configured to directly interface with the fluid distribution system 400 in the absence of external fluid conduits 502. Said differently, the direct mechanical connections 310, 312 may be configured to be removably attached with the fluid distribution system 400 without external fluid conduits 502 extending therebetween.

Although described herein with reference to the direct mechanical connections 310, 312 of the CDU 300, the present disclosure contemplates that these connection may be used by any component interfacing with the fluid distribution system 400. In some embodiments, for example, the server 202 may include a direct mechanical connection 210 coupled with the server inlet 206 and/or a direct mechanical connection 212 coupled with the server outlet 208. These direct mechanical connections 210, 212 may similarly remove or otherwise reduce the volume within the datacenter rack 102 that is occupied for the connection between the server 202 and the fluid distribution system 400. Similar to the CDU 300, the direct mechanical connections 210, 212 may be configured to directly interface with the fluid distribution system 400 in the absence of external fluid conduits.

In some embodiments, as shown in FIG. 6, the direct mechanical connections 210, 212, 310, 312 may include one or more blind mate connectors 600. As shown, the blind mate connectors 600 may include a first portion 602 that may, for example, be disposed on the CDU 300 (e.g., as direct mechanical connector 310, 312) and a second portion 604 that is disposed on the fluid distribution system 400, or vice versa. In operation, the first portion 602 may be received within the second portion 604 so as to establish fluid communication. As would be evident based upon the fluid nature of the thermal management solutions of the present disclosure, the connection provided by the blind mate connectors 600 may be water-tight or otherwise configured to contain the fluid therein (e.g., resistant to leaking). In other words, the mating between the first portion 602 and the second portion 604 may be such that the second portion substantially seals the first portion 602 from an external environment of the connectors 600. Although described herein with reference to blind mate connectors 600 as example direct mechanical connections, the present disclosure contemplates that direct mechanical connections of any type or configuration (e.g., manual connectors that do not rely upon hoses or the like) may be used based upon the intended application of the system 200. Although described herein with reference to direct mechanical connections (e.g., blind mate connectors 600 or the like) that are used for the fluid interfaces in the system 200, the present disclosure contemplates that these direct mechanical connections may be similarly used for other interfaces. By way of a non-limiting example, the server 202, the CDU 300, etc. may include direct mechanical electrical connectors, such as to facilitate power and/or data communications to the server 200, the CDU 300, etc.

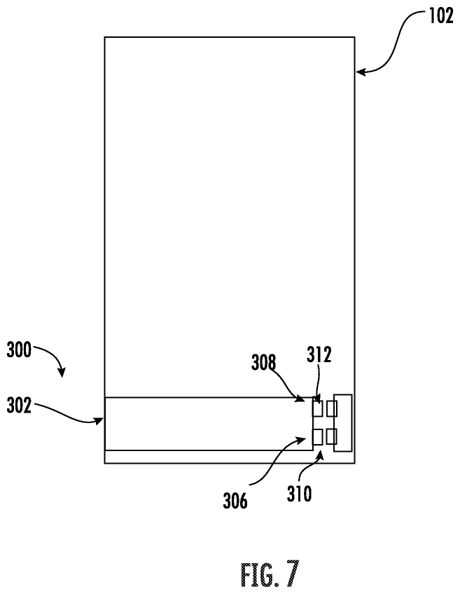

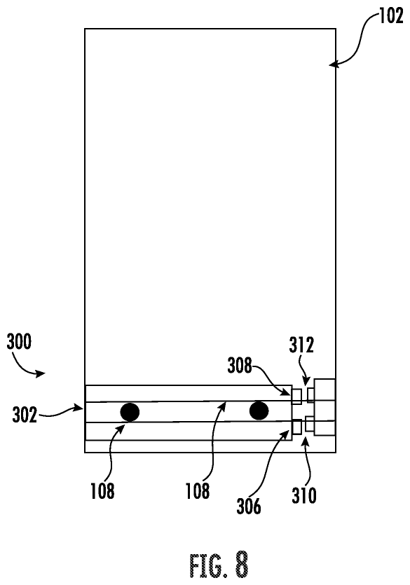

With reference to FIGS. 7-8, in some embodiments, the system 200 may be supported by a datacenter rack 102 such that the system 200 operates as an in-rack thermal management system. In such an embodiment, the housing 302 of the CDU 300 may define one or more support rails 108 by which the housing 302 may be positioned within the datacenter rack 102. In such an embodiment, the housing 302 of the CDU 300, via movement along the one or more support rails 108, may be configured to be removably attached with the fluid distribution system 400. For example, the housing 302 of the CDU 300 may translate along the support rails 108, and the fluid inlet 306 and associated direct mechanical connection 310 and the fluid outlet 308 and associated direct mechanical connection 312 may disengage from the fluid distribution system 400. Although illustrated and described herein with reference to example translation of the CDU 300 along support rails 108 for removal from the datacenter rack 102, the present disclosure contemplates that the CDU 300 may use any mechanism, technique, etc. to provide removal of the CDU 300 from the datacenter rack 102. Furthermore, although described herein with reference to the CDU 300, the present disclosure contemplates that the support rails 108 may be equally applicable to the server(s) 202 described above.

With reference to FIGS. 9-10, one or more example thermal management components 304 of an example CDU 300 are illustrated alongside the increased dimensions provided by the example CDUs 300. As shown in FIG. 9, for example, the thermal management components 304 may include, among other components, a heat exchanger 700, a power supply 702, a fill pump 704, and/or one or more internal fluid conduit(s) 706. As detailed above, however, the present disclosure contemplates that the thermal management components 304 may include any elements, features, devices, etc. used to dissipate heat generated in datacenter 100 implementations. For example, the thermal management components 304 may also include various sensors (e.g., temperature sensors, pressure sensors, etc.), valves (e.g., a primary valve, a secondary valve, etc.) and/or the like without limitation. The number and operational capacity of the thermal management components 304 may often be limited by the associated dimensions (e.g., size and shape) of the structure housing these components. By way of example, the housing 302 of the CDU 300 may be rectangular in cross-sectional shape such that the housing 302 defines a length (L), width (W), and height (H). Although described hereafter with reference to a rectangular prism shaped housing 302, the present disclosure contemplates that the housing 302 of the CDU 300 may have any shape based upon the intended application of the system 200.

With reference to FIG. 10, for example, the use of the direct mechanical connections 310, 312 to establish fluid communication with the fluid distribution system 400 may increase an internal dimension of the housing 302 such that additional internal volume 301 is provided by the CDU 300 that is unavailable in conventional solutions. By way of a particular example, the length (L) of the housing 302 may be increased relative to conventional solutions to provide this additional internal volume 301. Although illustrated with an increase to the length (L), the present disclosure contemplates that any dimensions of the housing 302 may be increased to provide this additional volume 301. In some embodiments, the internal volume increase 301 may be such that at least one of the thermal management components 304 supported by the housing includes an increased capacity. By way of example, the additional space 301 of the CDU 300 may be used to increase the size of the heat exchanger 700 and/or leverage a higher flow rate pump 704 within the CDU 300 so as to improve the heat dissipation provided by the CDU 300. In other embodiments, the internal volume increase 301 may be configured to support one or more redundant thermal management components 304′. For example, additional fluid pumps 704, sensors, etc. may be added to the CDU 300 which were historically unavailable due to the size limitations of the housing 302. Although described herein with reference to increasing the size of the housing 302 of the CDU 300, the present disclosure contemplates that the use of direct mechanical connections 310, 312 may be used to reduce the overall dimensions of the CDU 300 so as to support additional devices (e.g., an additional CDU 300, additional server(s) 202, etc.) within the datacenter rack 102 without modifying the dimensions of the datacenter rack 102.

Many modifications and other embodiments of the present disclosure set forth herein will come to mind to one skilled in the art to which these embodiments pertain having the benefit of the teachings presented in the foregoing descriptions and the associated drawings. Although the figures only show certain components of the methods and systems described herein, it is understood that various other components may also be part of any optical component or optoelectronic element.

Therefore, it is to be understood that the disclosure is not to be limited to the specific embodiments disclosed herein and that modifications and other embodiments are intended to be included within the scope of the appended claims. Although specific terms are employed herein, they are used in a generic and descriptive sense only and not for purposes of limitation.

That which is claimed:

1. A cooling distribution unit (CDU) comprising:
a housing defining:
a fluid inlet; and
a fluid outlet;
one or more thermal management components supported by the housing, wherein, in operation, the one or more thermal management components are configured to dissipate heat of a fluid received by the CDU via the fluid inlet; and
one or more direct mechanical connections coupled with the fluid inlet and the fluid outlet,
wherein the one or more direct mechanical connections are configured to directly interface with a fluid distribution system to provide fluid communication between the CDU and the fluid distribution system so as to maximize one or more dimensions of the housing.

2. The CDU according to claim 1, wherein the direct mechanical connections are configured to directly interface with the fluid distribution system in the absence of external fluid conduits.

3. The CDU according to claim 1, wherein the direct mechanical connections are configured to be removably attached with the fluid distribution system without external fluid conduits extending therebetween.

4. The CDU according to claim 1, wherein the one or more direct mechanical connections comprise one or more blind mate connectors.

5. The CDU according to claim 1, wherein a first temperature associated with the fluid received by the fluid inlet is greater than a second temperature associated with the fluid exiting the housing via the fluid outlet.

6. The CDU according to claim 1, wherein the housing further defines one or more support rails by which the housing may be positioned within a datacenter rack.

7. The CDU according to claim 6, wherein the housing, via movement along the one or more support rails, is configured to be removably attached with the fluid distribution system.

8. The CDU according to claim 1, wherein the one or more dimensions of the housing comprise an internal dimension such that the housing is further configured to support one or more redundant thermal management components.

9. The CDU according to claim 1, wherein the one or more dimensions of the housing comprise an internal dimension such that at least one of the thermal management components supported by the housing includes an increased capacity.

10. An in-rack thermal management system comprising:
a cooling distribution unit (CDU) comprising:
a housing defining:
a fluid inlet; and
a fluid outlet;
one or more thermal management components supported by the housing; and
one or more direct mechanical connections coupled with the fluid inlet and the fluid outlet; and
a fluid distribution system comprising:
a primary fluid channel directly coupled with the direct mechanical connection of the fluid inlet; and
a secondary fluid channel directly coupled with the direct mechanical connection of the fluid outlet,
wherein, in operation, the one or more thermal management components are configured dissipate heat of a fluid received by the CDU via the fluid inlet, and
wherein the direct mechanical connections are configured to directly interface with the fluid distribution system to provide fluid communication between the CDU and the fluid distribution system so as to maximize one or more dimensions of the housing.

11. The in-rack thermal management system according to claim 10, wherein the direct mechanical connections are configured to directly interface with the fluid distribution system in the absence of external fluid conduits.

12. The in-rack thermal management system according to claim 10, wherein the direct mechanical connections are configured to be removably attached with the fluid distribution system without external fluid conduits extending therebetween.

13. The in-rack thermal management system according to claim 10, wherein the one or more direct mechanical connections comprise one or more blind mate connectors.

14. The in-rack thermal management system according to claim 10, wherein a first temperature associated with the fluid received by the fluid inlet is greater than a second temperature associated with the fluid exiting the housing via the fluid outlet.

15. The in-rack thermal management system according to claim 10, wherein the housing further defines one or more support rails by which the housing may be positioned within a datacenter rack.

16. The in-rack thermal management system according to claim 15, wherein the housing, via movement along the one or more support rails, is configured to be removably attached with the fluid distribution system.

17. The in-rack thermal management system according to claim 10, wherein the one or more dimensions of the housing comprise an internal dimension such that the housing is further configured to support one or more redundant thermal management components.

18. The in-rack thermal management system according to claim 10, wherein the one or more dimensions of the housing comprise an internal dimension such that at least one of the thermal management components supported by the housing includes an increased capacity.

19. The in-rack thermal management system according to claim 10, further comprising:
a server housing defining:
a server inlet; and
a server outlet;
one or more processing components supported by the server housing;
one or more direct mechanical connections coupled with the server inlet and the server outlet,
wherein the one or more direct mechanical connections are configured to directly interface with the fluid distribution system to provide fluid communication between the server housing and the fluid distribution system.

20. The in-rack thermal management system according to claim 19, wherein the direct mechanical connections of the server housing are configured to directly interface with the fluid distribution system in the absence of external fluid conduits.
